(19) United States
(12) Patent Application Publication
(10) Pub. No.: US 2026/0143893 A1
(43) Pub. Date: May 21, 2026

(54) PRINTABLE AND LIGHTWEIGHT ALUMINUM FOIL-BASED PEROVSKITE FILMS AND DEVICES AND METHODS OF MAKING THE SAME

(71) Applicant: Feng YAN, Chandler, AZ (US)

(72) Inventor: Feng YAN, Chandler, AZ (US)

(73) Assignee: Arizona Board of Regents on Behalf of Arizona State University, Scottsdale, AZ (US)

(21) Appl. No.: 19/372,136

(22) Filed: Oct. 28, 2025

Related U.S. Application Data
(60) Provisional application No. 63/721,951, filed on Nov. 18, 2024.

(51) Int. Cl. H10K 30/82; H10K 30/40; H10K 71/60

(52) U.S. Cl. CPC H10K 30/82; H10K 30/40; H10K 71/60

(57) ABSTRACT

A solar cell includes a transparent electrode and a hole transport layer (HTL) coupled to and disposed underneath the transparent electrode. The solar cell includes a light-absorbing layer made of a perovskite photovoltaic material that is coupled to the HTL opposite the transparent electrode. The solar cell includes an electron transport layer (ETL) made of tin oxide (SnO2) coupled to the light-absorbing layer opposite the HTL. The solar cell includes a bottom electrode made of a carbon material coupled to the ETL opposite the light-absorbing layer. The solar cell includes a substrate made of aluminum or an aluminum alloy coupled to the bottom electrode opposite the ETL.

### RELATED APPLICATIONS

This application claims the benefit of U.S. provisional patent application No. 63/721,951, filed Nov. 18, 2024 to Yang, titled “ALUMINUM FOIL-BASED PEROVSKITE FILMS AND DEVICES AND METHODS OF MAKING THE SAME,” the entirety of the disclosure of which is hereby incorporated by this reference.

### STATEMENT REGARDING FEDERALLY SPONSORED RESEARCH OR DEVELOPMENT

This invention was made with government support under 2329871 awarded by the National Science Foundation. The government has certain rights in the invention.

### TECHNICAL FIELD

Embodiments of the present disclosure relate generally to materials and methods of manufacture for solar electrical power generation. More specifically, disclosed embodiments are directed to aluminum foil-based perovskite films and devices and methods of making the same.

### BACKGROUND

Solar energy is the most abundant energy source in the world. A solar cell converts solar energy into electricity. The power conversion efficiency of the solar cell determines how much solar energy is converted into electrical energy. To ensure widespread adoption of solar energy, lower-cost solutions that are compatible with large-scale production are needed.

### SUMMARY

In some embodiments, a solar cell includes a transparent electrode, a hole transport layer (HTL) coupled to and disposed underneath the transparent electrode, a light absorbing layer comprising a perovskite photovoltaic material coupled to the HTL opposite the transparent electrode, an electron transport layer (ETL) comprising tin oxide (SnO2) coupled to the light absorbing layer opposite the HTL, a bottom electrode comprising a carbon material coupled to the ETL opposite the light absorbing layer, and a substrate comprising aluminum or an aluminum alloy coupled to the bottom electrode opposite the ETL. The carbon material may be a paste, a film, a foam or sponge, or a graphite sheet. The carbon material may be a thermoplastic paste. The substrate may be a sheet, a foil, a mesh, a fabric, a composite, a plurality of nanowires, or a woven material. The HTL may include CuSCN, NiOₓ, polytriarylamine (PTAA), poly(3,4-ethylenedioxythiophene), polystyrene sulfonate (PEDOT), graphene oxide, reduced graphene oxide (rGO), or Spiro-OMeTAD. The transparent electrode may include aluminum zinc oxide (AlZnO).

In some embodiments, a solar cell includes a transparent electrode, an electron transport layer (ETL) coupled to and disposed underneath the transparent electrode, a light absorbing layer comprising a perovskite photovoltaic material coupled to the ETL opposite the transparent electrode, a hole transport layer (HTL) coupled to the light absorbing layer opposite the ETL, a bottom electrode comprising a carbon material coupled to the HTL opposite the light absorbing layer, and a substrate comprising aluminum or an aluminum alloy coupled to the bottom electrode opposite the HTL. The carbon material may be a paste, a film, a foam or sponge, or a graphite sheet. The electron transport layer may include titanium dioxide (TiO₂), zinc oxide (ZnO), fullerene-based compounds, gallium oxide, or graphene. The carbon material may be a thermoplastic paste. The hole transport layer may include copper(I) thiocyanate (CuSCN), nickel oxide (NiOₓ), Spiro-OMeTAD, polytriarylamine (PTAA), poly(3,4-ethylenedioxythiophene): polystyrene sulfonate (PEDOT:PSS), graphene oxide, or reduced graphene oxide. The substrate may be a sheet, a foil, a mesh, a composite, a plurality of nanowires, or a woven material. The HTL may include CuSCN, NiOₓ, PTAA, poly(3,4-ethylenedioxythiophene), PEDOT, graphene oxide, rGO, or Spiro-OMeTAD. The transparent electrode may include aluminum zinc oxide (AlZnO).

In some embodiments, a method of making a perovskite solar cell includes cleaning an aluminum substrate, where the aluminum substrate may be a sheet, a foil, a mesh, a composite, a plurality of nanowires, or a woven material, forming a bottom electrode comprising a carbon material over the aluminum substrate, forming an electron transport layer (ETL) comprising tin oxide (SnO₂) over the bottom electrode, forming a perovskite photovoltaic material over the ETL layer using dynamic or static spin coating, sol-gel processing, solution casting, spray coating, dip coating, or atomic layer deposition (ALD), forming a hole transport layer (HTL) over the perovskite photovoltaic material using dynamic or static spin coating, sol-gel processing, solution casting, spray coating, or dip coating, and depositing a transparent electrode comprising aluminum zinc oxide (AlZnO) over the HTL using a sputtering process. The carbon material may be a paste, a film, a foam or sponge, or a graphite sheet. The carbon material may be a thermoplastic paste. Curing the carbon paste may include heating at a temperature from about 70° C. to about 90° C. for about 5 minutes. Forming the electron transport layer may include depositing tin oxide by spin coating, spray coating, sol-gel processing, solution casting, or drop-dry deposition. Depositing the transparent electrode may include sputtering aluminum zinc oxide (AlZnO) using a physical vapor deposition process.

The foregoing and other aspects, features, and advantages will be apparent from the DESCRIPTION and DRAWINGS, and from the CLAIMS if any are included.

### BRIEF DESCRIPTION OF THE DRAWINGS

Implementations will hereinafter be described in conjunction with the appended and/or included DRAWINGS, where like designations denote like elements, and:

FIG. 1 illustrates a prior art flexible perovskite solar cell that utilizes an indium tin oxide (ITO)-coated polymer substrate with a noble metal electrode.

FIG. 2 is a chart illustrating representative power-conversion efficiency trends for photovoltaic cell technologies over time.

FIG. 3 shows a cross-section diagram of a perovskite solar cell according to some embodiments.

FIG. 4 shows a cross-section diagram of a perovskite solar cell according to some embodiments.

FIG. 5 shows a view illustrating the formation of a patterned carbon bottom electrode on an aluminum foil substrate.

FIG. 6 shows Graph showing representative current density-voltage (J-V) characteristics of an example device fabricated on an aluminum-foil substrate with a carbon bottom electrode.

### DETAILED DESCRIPTION

The following detailed description provides numerous specific details. Those skilled in the relevant arts understand that embodiments of the disclosure may be practiced without these specific details. The disclosure may also be practiced in different and alternative configurations.

Unless specifically noted, it is intended that the words and phrases in the specification and the claims be given their plain, ordinary, and accustomed meaning to those of ordinary skill in the applicable arts. The singular forms “a,” “an,” and “the” include plural referents unless the context clearly dictates otherwise. Thus, for example, a reference to “a step” includes a reference to one or more of such steps. The words “exemplary,” “example,” “embodiment,” or various forms thereof are used herein to mean serving as an example, instance, or illustration. Any aspect or feature described herein as “exemplary” or as an “example” is not necessarily to be construed as preferred or advantageous over other aspects or designs. The examples are provided solely for purposes of clarity and understanding and do not limit or restrict the disclosure. It is to be appreciated that a myriad of additional or alternate examples of varying scope could have been presented, but have been omitted for purposes of brevity.

Throughout the description and claims of this specification, the words “comprise” and “contain” and variations of the words, for example “comprising” and “comprises”, mean “including but not limited to”, and are not intended to (and do not) exclude other components.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one.

Embodiments of the present disclosure are directed to solar cells and methods of making the same. A myriad of technologies have been proposed to increase the efficiency of solar cells. Most are cost-prohibitive—particularly at scale. Many substrates for use in solar cells contain costly noble metals such as gold, silver, and copper or indium tin oxide (ITO) electrodes. Conventional solar cells utilize a rigid glass substrate. This increases weight and rigidity beyond an acceptable limit for many applications where a lighter weight and greater flexibility are desired, such as in space applications and wearable electronics applications.

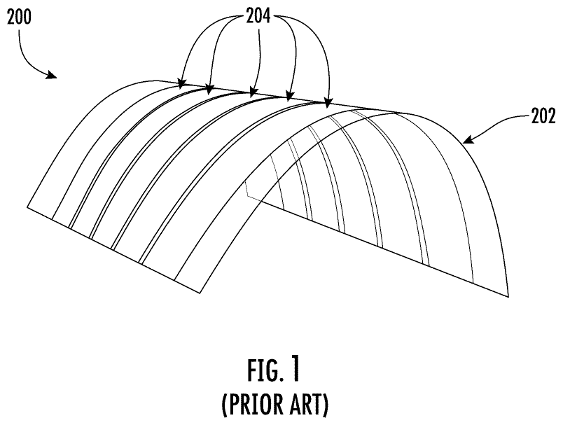

FIG. 1 shows a prior art flexible perovskite solar cell 200. The prior art flexible perovskite solar cell 200 utilizes an indium tin oxide-coated polymer substrate 202 with noble metal electrodes 204. Typically, the prior art flexible perovskite solar cell 200's polymer substrate is a polyethylene naphthalate (PEN) film. The noble metal electrodes 204 are made of gold.

The prior art flexible perovskite solar cell 200 is costly to manufacture, particularly in high-volume manufacturing environments. Gold and ITO are expensive materials. The prior art flexible perovskite solar cell 200 also suffers from numerous reliability challenges. While PEN substrates are mechanically flexible, ITO coatings are brittle, making them susceptible to cracking and delamination when subjected to stress or bending. In addition, ITO, PEN, and gold each have different thermal expansion coefficients, and when used in environments where thermal variations occur, such as outdoor environments, the difference in thermal expansion coefficients can create stress at interfaces between ITO, PEN, and gold, leading to microcracks or delamination. All these can cause electrical disconnection or increased resistance in the module or cell. Additionally, poor adhesion between ITO and PEN can lead to delamination, particularly in applications where the cell or module is subjected to bending or flexion. This delamination disrupts the conductivity path, impacting the efficiency and longevity of the module.

Furthermore, gold atoms may diffuse into the perovskite layer through any pinholes or imperfections in the ITO, which can lead to deterioration in the perovskite layer's optical and electronic properties, ultimately impacting the module's stability over time. During use, the cells or modules may be exposed to varying levels of moisture, oxygen, and ultraviolet light. Both PEN and ITO provide a limited barrier to the penetration of oxygen and moisture. Moisture can lead to perovskite decomposition, while oxygen can oxidize ITO, degrading its conductivity. Prolonged UV exposure can degrade the PEN substrate and affect the ITO's optical and conductive properties, reducing the transparency and efficiency of the module.

Embodiments of the present disclosure are directed to a flexible perovskite solar cell (PVSK) with aluminum (Al) foil-based electrodes. In some embodiments, the aluminum foil-based electrodes are flexible, lightweight, and low-cost. According to some embodiments, the aluminum foil-based electrodes may further comprise a carbon-based buffer layer having a high carrier transport capability as part of the electrode. The aluminum foil-based perovskite film may be printable and lightweight. The integration of aluminum foil-based perovskite films into devices, such as perovskite-based solar cells, may provide a cost-effective and scalable high-efficiency solar cell technology.

Embodiments of the disclosed flexible perovskite solar cell can be utilized in various applications. For example, embodiments of the solar cell disclosed herein may be useful in space, automotive, flexible and portable indoor or outdoor solar cells, agrivoltaics, greenhouse applications, and vehicular applications. In some embodiments, the PVSKs disclosed herein may be embodied in architectural designs to provide energy. Additionally, the PVSK may be particularly useful as an energy source for wearable electronics, consumer electronics, Internet of Things (IoT) devices, transportation, and automotive applications. Other applications of the disclosed PVSKs are also within the scope of this disclosure.

Embodiments of the disclosed PVSKs overcome the barriers to use of aluminum-based electrodes. Specifically, disclosed embodiments utilize a buffer layer with high carrier transport capability, such as a carbon material or carbon paste, and a hole transport layer. The disclosed embodiments utilize a highly conductive metal as a back contact or bottom electrode.

The advantages of using aluminum materials, such as aluminum foils, to replace the ITO-coated PEN substrate (as seen in FIG. 1) of the prior art are numerous. Aluminum foil is less brittle than ITO. It is less prone to cracking under stress. Aluminum may also provide a better option for flexible or bendable solar applications, where mechanical stability is essential. Aluminum can adhere more effectively to certain substrates compared to ITO. If the adhesion between the aluminum foil and the perovskite or a protective layer is optimized, this may reduce the risk of delamination that occurs with ITO. Aluminum's thermal expansion properties are more compatible with flexible substrates like PEN than those of ITO, reducing the risk of stress and cracking due to temperature variations. Aluminum has a lower tendency to diffuse into adjacent layers than gold. This helps maintain the integrity of the perovskite layer and prevents deterioration of the perovskite layer's optical and electronic properties. A properly encapsulated aluminum is resistant to oxidation and corrosion, especially when compared to ITO. ITO can also degrade under prolonged moisture and UV exposure.

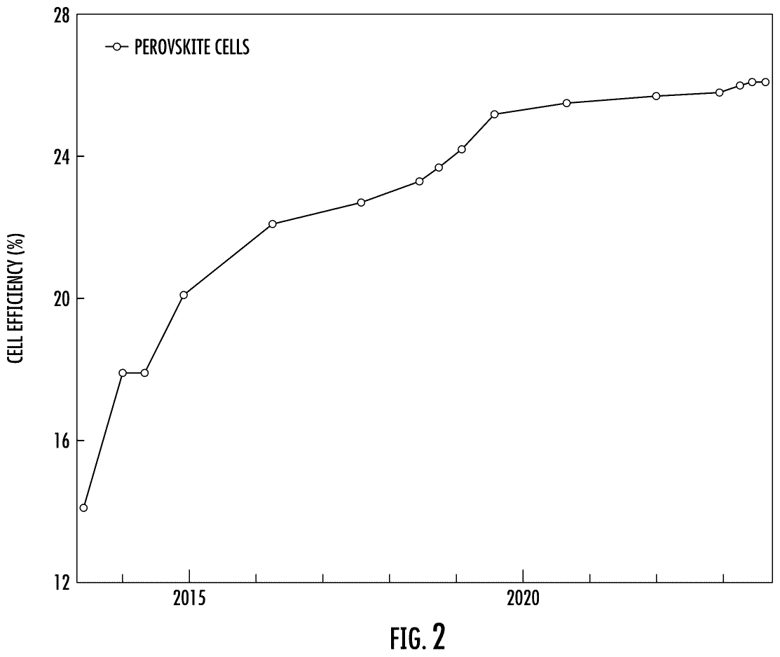

FIG. 2 illustrates increases in overall PVSK cell efficiency across differing technologies from 2013 to 2024. As shown, PVSK cells as a group have increased in efficiency from about 14% in 2013 to about 26.2% in 2024.

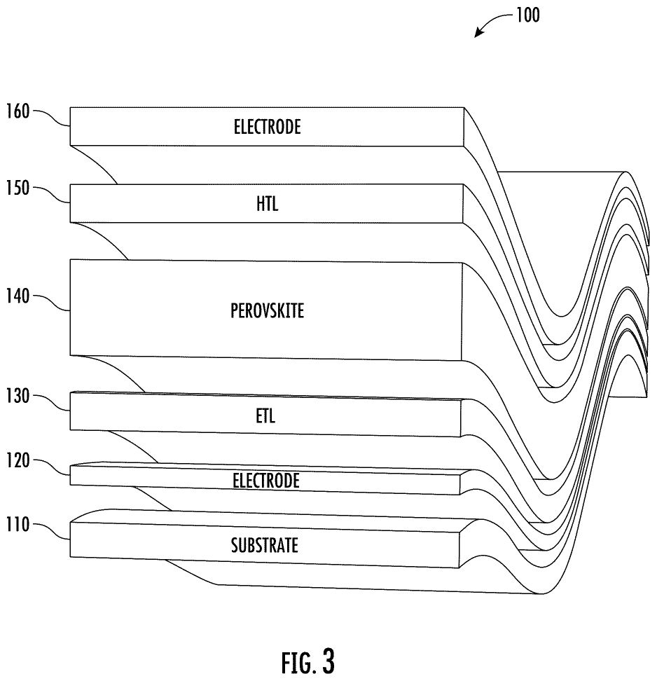

FIG. 3 shows a cross-section diagram of a perovskite solar cell 100, according to some embodiments. Perovskite solar cell 100 includes many layers. Each will be described in detailed below.

In some embodiments, perovskite solar cell 100 has a substrate 110. In some embodiments, substrate 110 comprises aluminum or an aluminum alloy, such as foil, for lightweight, high-conductivity applications, including space and wearable electronics. Aluminum foil offers a cost-effective alternative to rigid substrates and can also be provided in various forms, including sheets, fabrics, meshes, composites, nanowire arrays, or woven materials. In some embodiments, the substrate comprises polyethylene naphthalate (PEN) alone or PEN laminated with an aluminum foil or layer. Prior to bottom electrode deposition, the aluminum substrate may be cleaned using combinations of detergent, water, acetone, ethanol, and isopropanol to remove residual polymers, surface contaminants, or particulates.

An electrode 120 is disposed on substrate 110. Electrode 120 may be deposited on the substrate 110. In some embodiments, electrode 120 includes a carbon material provided as a paste, film, foam, sponge, or graphite sheet. In some embodiments, the carbon material is a carbon-based thermoplastic paste with high conductivity. Electrode 120 may be applied to substrate 110 by screen or stencil printing, doctor blade casting, or similar techniques. In some embodiments, electrode 120 may require curing after application to substrate 110. Electrode 120 may include an aluminum component, such as a foil or mesh with carbon paste disposed thereon. For example, an aluminum foil coated with carbon paste may serve as the bottom electrode over a flexible PEN substrate. Various combinations of aluminum foil, carbon material, and PEN substrate are contemplated within the scope of this disclosure.

An electron transport layer (ETL) 130 is disposed on electrode 120. In some embodiments, ETL 130 comprises tin oxide (SnO₂), such as n-type SnO₂. ETL 130 may be deposited by solution-based methods, including spin coating, spray coating, sol-gel processing, solution casting, drop-dry deposition, or sputtering. Alternative ETL materials include titanium dioxide (TiO₂), zinc oxide (ZnO), fullerene compounds (e.g., C₆₀, PCBM), gallium oxides, and graphene, which may be applied using similar techniques.

ETL 130 supports a light-absorbing layer comprising a perovskite photovoltaic material 140. In some embodiments, perovskite photovoltaic material 140 is provided as an ink or precursor solution containing metal salts, polymer blends, or polymer-fullerene blends dissolved in a suitable solvent. Deposition methods may include dynamic or static spin coating, sol-gel processing, solution casting, spray coating, doctor-blade coating, dip coating, or atomic layer deposition (ALD), among others.

A hole transport layer (HTL) 150 is disposed on perovskite photovoltaic material 140. In some embodiments, HTL 150 includes CuSCN, NiOx, or Spiro-OMeTAD. In some embodiments, HTL 150 comprises polytriarylamine (PTAA), poly(3,4-ethylenedioxythiophene): polystyrene sulfonate (PEDOT:PSS), graphene oxide (GO), or reduced graphene oxide (rGO). HTL 150 may be formed by one or more of dynamic or static spin coating, sol-gel processing, solution casting, spray coating, dip coating, or atomic layer deposition (ALD), among other methods.

An electrode 160 may be formed over HTL 150. In some embodiments, electrode 160 is transparent. Electrode 160 may comprise aluminum-doped zinc oxide (AlZnO). Electrode 160 may be deposited by sputtering, co-sputtering, pulsed laser deposition, sol-gel processes, or atomic layer deposition (ALD), with other techniques employed as required by the product.

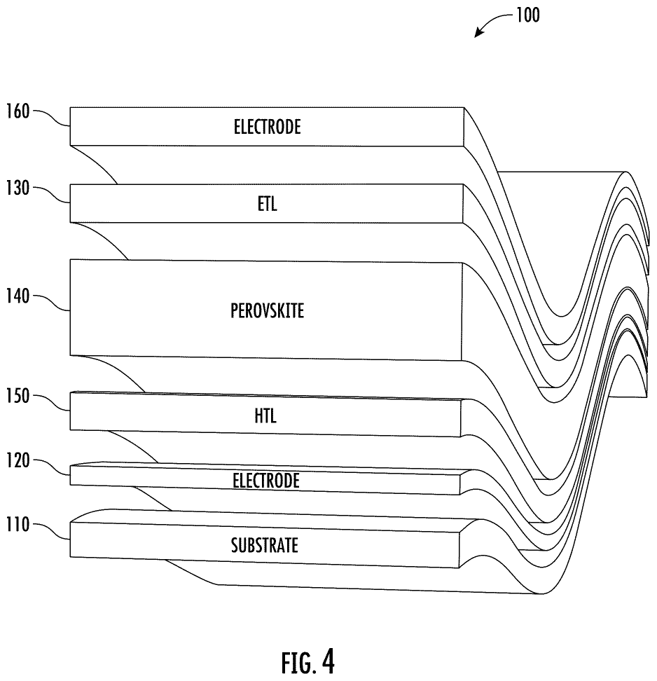

The embodiment of perovskite solar cell 100 shown in FIG. 3 may be described as a nip structure. FIG. 4 shows a cross-section diagram of a perovskite solar cell 100, according to some embodiments. Unlike the embodiment shown in FIG. 3, the embodiment shown in FIG. 4 is a pin structure. Perovskite solar cell 100 shown in FIG. 4 has HTL 150 disposed adjacent to the bottom electrode 120. ETL 130 is disposed adjacent to the top electrode 160. The techniques and materials described for the nip structure of the PVSK cell may similarly be used for the pin structure of the PVSK cell.

In some embodiments, PVSK cell 100 comprises an interdigitated back-contact (IBC) architecture in which the top and bottom electrodes of FIGS. 3 and 4 are disposed as back-contact structures. In such embodiments, the positive and negative electrodes are separately patterned as part of the back contact of the PVSK cell, using the materials and methods disclosed herein.

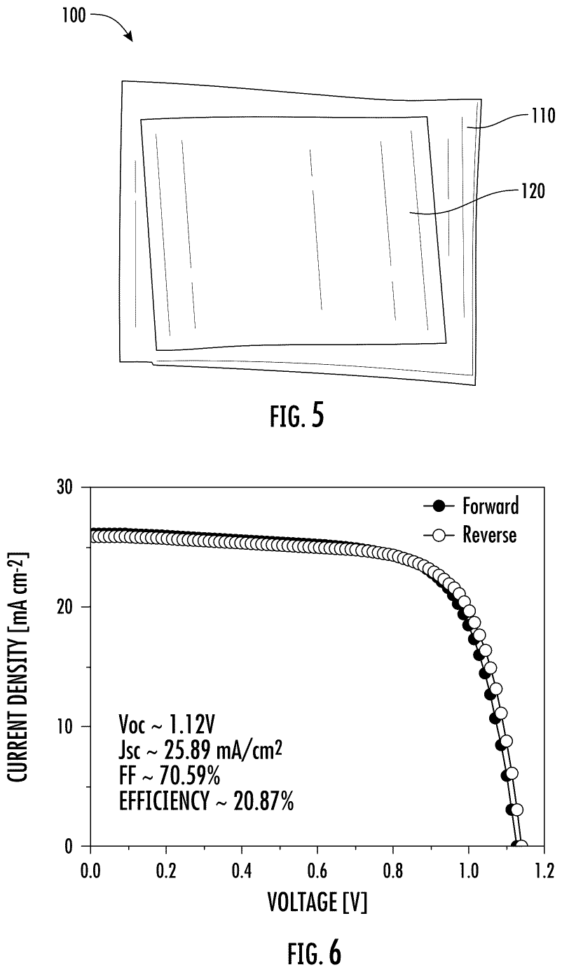

FIG. 5 shows a view illustrating the formation of a patterned carbon bottom electrode 120 on an aluminum foil substrate 110. The bottom electrode 120 may comprise a carbon paste. The carbon paste may be screen or stencil printed onto the substrate. According to some embodiments where the carbon material comprises a carbon paste or a thermoplastic carbon paste, the carbon paste may be cured after being disposed onto the flexible substrate at temperatures of from about 70° C. to about 90° C., preferably about 80° C., for a duration of about 5 minutes.

FIG. 6 illustrates cyclic voltammetry results for embodiments of the disclosed PVSK cell comprising an aluminum foil and carbon paste electrode as disclosed herein, providing an efficiency of greater than 20%. Using the materials and methods disclosed herein, the PVSK cell device can be fabricated, comprising cross-sectional areas of 1 m² or greater for industrial implementation. In some embodiments, the device may have an area between 0.1 cm² and 100 cm². The device may be other sizes in some embodiments.

More specifically, this disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

Many additional implementations are possible. Further implementations are within the CLAIMS.

It will be understood that implementations of the preceding disclosure include but are not limited to the specific components disclosed herein, as virtually any components consistent with the intended operation may be utilized. Accordingly, for example, it should be understood that, while the drawings and accompanying text show and describe particular implementations, any such implementation may comprise any shape, size, style, type, model, version, class, grade, measurement, concentration, material, weight, quantity, and/or the like consistent with the intended operation.

The concepts disclosed herein are not limited to the specific embodiments shown herein. For example, it is specifically contemplated that the components included in particular embodiments may be formed of any of many different types of materials or combinations that can readily be formed into shaped objects and that are consistent with the intended operation of the disclosure. For example, the components may be formed of: rubbers (synthetic and/or natural) and/or other like materials; glasses (such as fiberglass), carbon-fiber, aramid-fiber, any combination therefore, and/or other like materials; elastomers and/or other like materials; polymers such as thermoplastics (such as ABS, fluoropolymers, polyacetal, polyamide, polycarbonate, polyethylene, polysulfone, and/or the like, thermosets (such as epoxy, phenolic resin, polyimide, polyurethane, and/or the like), and/or other like materials; plastics and/or other like materials; composites and/or other like materials; metals, such as zinc, magnesium, titanium, copper, iron, steel, carbon steel, alloy steel, tool steel, stainless steel, spring steel, aluminum, and/or other like materials; and/or any combination of the foregoing.

Furthermore, embodiments of the present disclosure may be manufactured separately and then assembled together, or any or all of the components may be manufactured simultaneously and integrally joined with one another. Manufacture of these components separately or simultaneously, as understood by those of ordinary skill in the art, may involve 3-D printing, extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled or removably coupled with one another in any manner, such as with adhesive, a weld, a fastener, any combination thereof, and/or the like for example, depending on, among other considerations, the particular material(s) forming the components.

In places where the description above refers to particular implementations, it should be readily apparent that a number of modifications may be made without departing from the spirit thereof and that these implementations may be applied to other implementations disclosed or undisclosed. The presently disclosed are, therefore, to be considered in all respects as illustrative and not restrictive.

What is claimed is:

1. A solar cell comprising:
a transparent electrode;
a hole transport layer (HTL) coupled to and disposed underneath the transparent electrode;
a light absorbing layer comprising a perovskite photovoltaic material coupled to the HTL opposite the transparent electrode;
an electron transport layer (ETL) comprising tin oxide (SnO2) coupled to the light absorbing layer opposite the HTL;
a bottom electrode comprising a carbon material coupled to the ETL opposite the light absorbing layer, and
a substrate comprising aluminum or an aluminum alloy coupled to the bottom electrode opposite the ETL.

2. The solar cell of claim 1, wherein the carbon material comprises at least one form selected from the group consisting of: a paste, a film, a foam or sponge, and a graphite sheet.

3. The solar cell of claim 1, wherein the carbon material comprises a thermoplastic paste.

4. The solar cell of claim 1, wherein the substrate comprises a sheet, a foil, a mesh, a fabric, a composite, a plurality of nanowires, or a woven material.

5. The solar cell of claim 1, wherein the HTL comprises at least one of CuSCN, NiOx, Polytriarylamine (PTAA), Poly(3,4-ethylenedioxythiophene), Polystyrene Sulfonate (PEDOT), Graphene Oxide, Reduced Graphene Oxide (rGO) and Spiro-OMeTAD.

6. The solar cell of claim 1, wherein the transparent electrode comprises aluminum zinc oxide (AlZnO).

7. A solar cell comprising:
a transparent electrode;
an electron transport layer (ETL) coupled to and disposed underneath the transparent electrode;
a light absorbing layer comprising a perovskite photovoltaic material coupled to the ETL opposite the transparent electrode;
a hole transport layer (HTL) coupled to the light absorbing layer opposite the ETL;
a bottom electrode comprising a carbon material coupled to the HTL opposite the light absorbing layer, and
a substrate comprising aluminum or an aluminum alloy coupled to the bottom electrode opposite the HTL.

8. The solar cell of claim 7, wherein the carbon material comprises at least one form selected from the group consisting of: a paste, a film, a foam or sponge, and a graphite sheet.

9. The solar cell of claim 7, wherein the electron transport layer comprises a material selected from the group consisting of titanium dioxide (TiO₂), zinc oxide (ZnO), fullerene-based compounds, gallium oxide, and graphene.

10. The solar cell of claim 7, wherein the carbon material comprises a thermoplastic paste.

11. The solar cell of claim 7, wherein the hole transport layer comprises a material selected from the group consisting of copper(I) thiocyanate (CuSCN), nickel oxide (NiOₓ), Spiro-OMeTAD, polytriarylamine (PTAA), poly(3,4-ethylenedioxythiophene): polystyrene sulfonate (PEDOT:PSS), graphene oxide, and reduced graphene oxide.

12. The solar cell of claim 7, wherein the substrate comprises a sheet, a foil, a mesh, a composite, a plurality of nanowires, or a woven material.

13. The solar cell of claim 7, wherein the HTL comprises at least one of CuSCN, NiOx, Polytriarylamine (PTAA), Poly(3,4-ethylenedioxythiophene), Polystyrene Sulfonate (PEDOT), Graphene Oxide, Reduced Graphene Oxide (rGO) and Spiro-OMeTAD.

14. The solar cell of claim 7, wherein the transparent electrode comprises aluminum zinc oxide (AlZnO).

15. A method of making a perovskite solar cell, the method comprising:
cleaning an aluminum substrate, wherein the aluminum substrate comprises a sheet, a foil, a mesh, a composite, a plurality of nanowires, or a woven material;
forming a bottom electrode comprising a carbon material over the aluminum substrate;
forming an electron transport layer (ETL) comprising tin oxide (SnO2) over the bottom electrode;
forming a perovskite photovoltaic material over the ETL layer using one or more of: dynamic or static spin coating, sol-gel processing, solution casting, spray coating, dip coating and atomic layer deposition (ALD);
forming a hole transport layer (HTL) over the perovskite photovoltaic material using one or more of: dynamic or static spin coating, sol-gel processing, solution casting, spray coating, and dip coating; and
depositing a transparent electrode comprising aluminum zinc oxide (AlZnO) over the HTL using a sputtering process.

16. The method of making a perovskite solar cell of claim 15, wherein the carbon material comprises at least one form selected from the group consisting of: a paste, a film, a foam or sponge, and a graphite sheet.

17. The method of making a perovskite solar cell of claim 15, wherein the carbon material comprises a thermoplastic paste.

18. The method of claim 15, wherein curing the carbon paste comprises heating at a temperature from about 70° C. to about 90° C. for a duration of about 5 minutes.

19. The method of claim 15, wherein forming the electron transport layer comprises depositing tin oxide by a solution processing technique selected from the group consisting of spin coating, spray coating, sol-gel processing, solution casting, and drop-dry deposition.

20. The method of claim 15, wherein depositing the transparent electrode comprises sputtering aluminum zinc oxide (AlZnO) using a physical vapor deposition process.
